(19) United States
(12) Patent Application Publication
(10) Pub. No.: US 2006/0086320 A1
(43) Pub. Date: Apr. 27, 2006

(54) Method and device for plasma treating workpieces

(76) Inventors: Michael Lizenberg, Geesthacht (DE); Frank Lewin, Tangstedt (DE); Hartwig Muller, Lutjensee (DE); Klaus Vogel, Barsbuttel (DE); Gregor Arnold, Bodenheim (DE); Stephan Behle, Hahnheim (DE); Andreas Luttringhaus-Henkel, Darmstadt (DE); Matthias Bicker, Mainz (DE); Jurgen Klein, Mainz (DE)

Correspondence Address: FRIEDRICH KUEFFNER, 317 MADISON AVENUE, SUITE 910, NEW YORK, NY, 10017, US

(21) Appl. No.: 10/515,606

(22) PCT Filed: May 9, 2003
(86) PCT No.: PCT/DE03/01501

§ 371 Date: Aug. 1, 2005

(30) Foreign Application Priority Data
May 24, 2002 (DE) 102 23 288.1
Jun. 1, 2002 (DE) 102 24 395.6

(51) Int. Cl. C23C 16/00; B05D 7/22

(52) U.S. Cl. 118/719; 118/723 MW; 427/230

(57) ABSTRACT

Disclosed are a method and a device for plasma treating workpieces (5). Said workpiece is inserted into a chamber (4) of a treatment station (17), which can be at least partly evacuated, and at least one part (18) of the treatment station is moved relative to another part (27, 35) thereof in order to help manipulate the workpieces. The movement is carried out in such a way that a shell-shaped chamber wall (18) is positioned relative to a floor (35) of the chamber and relative to a chamber lid (27).

The invention concerns a method for the plasma treatment of workpieces, wherein the workpiece is inserted in a plasma chamber of a treatment station, which can be at least partially evacuated, and wherein, to assist in the handling of the workpieces, at least one part of the treatment station is moved relative to at least one other part.

The invention also concerns a device for the plasma treatment of workpieces, which has at least one plasma chamber, which can be evacuated, for holding the workpieces, in which the plasma chamber is located in the area of a treatment station, and in which the plasma chamber is bounded by a chamber floor, a chamber lid, and a lateral chamber wall.

Processes and devices of this type are used, for example, to apply surface coatings to plastics. In particular, processes and devices of this type are also already known for coating inner or outer surfaces of containers used for holding liquids. Devices for plasma sterilization are also well known.

PCT-WO 95/22413 describes a plasma chamber for coating the inner surface of PET bottles. The bottles to be coated are raised into a plasma chamber by a movable base and connected at their mouths to an adapter. The inside of the bottles can be evacuated through the adapter. A hollow lance for supplying process gas is also inserted into the inside of the bottles through the adapter. Microwaves are used to ignite the plasma.

The same publication also describes the arrangement of a plurality of plasma chambers on a rotating wheel. This helps achieve a high production rate of bottles per unit time.

EP-OS 10 10 773 describes a feeding device for evacuating the inside of a bottle and supplying it with process gas. PCT-WO 01/31680 describes a plasma-chamber into which the bottles are introduced by a movable lid that has first been connected with the mouths of the bottles.

PCT-WO 00/58631 also describes the arrangement of plasma stations on a rotating wheel and the assignment of groups of vacuum pumps and plasma stations for an arrangement of this type to help provide favorable evacuation of the chambers and the interiors of the bottles. It also mentions the coating of several containers in a common plasma station or a common cavity.

Another system for coating the inside surfaces of bottles is described in PCT-WO 99/17334. This document describes especially an arrangement of a microwave generator above the plasma chamber and means for evacuating the plasma chamber and feeding it operating agents through the floor of the plasma chamber.

In most of the previously known methods, silicon oxide coatings, which have the general chemical formula SiOₓ and are produced by the plasma, are used to improve the barrier properties of the thermoplastic material. Barrier layers of this type prevent oxygen from penetrating the bottled liquids and prevent the escape of carbon dioxide from liquids that contain CO₂.

The previously known methods and devices are still not sufficiently suitable for use in a mass-production process, in which it is necessary to achieve both a low coating cost per workpiece and a high production rate.

Therefore, the objective of the present invention is to develop a method of the aforementioned type in such a way that the workpieces to be treated can be handled at high speed and with a high degree of reliability.

In accordance with the invention, this objective is achieved by positioning a sleeve-like chamber wall relative to a chamber floor and relative to a chamber lid.

A further objective of the present invention is to design a device of the aforementioned type that allows simple motion (kinematics) of the workpieces to be treated.

In accordance with the invention, this objective is achieved by designing the chamber wall in the form of a sleeve that can be movably positioned relative to both the chamber floor and the chamber lid.

The ability to position the sleeve-like chamber wall relative to the chamber floor and the chamber lid makes it possible to convey the workpieces to be treated at an essentially constant height level. This saves the time required to carry out a height positioning in accordance with prior-art methods as well as the associated constructional expense. The chamber floor and the chamber lid remain positioned at a constant height level, so that simple design measures can be used to arrange a microwave generator near the chamber lid for igniting the plasma and to arrange means for evacuating the chamber and for feeding process gas to the chamber near the chamber floor. All feed lines for operating agents and power supply lines can thus take the form of permanent lines, and couplings or flexible lines, which are critical with respect to their service life, can be eliminated.

The process-engineering sequence involved in the handling of the workpieces occurs in such a way that the movable sleeve is first moved in a way that makes it possible to insert the workpiece to be treated in the chamber. After the workpiece has been inserted in the chamber, the sleeve-like chamber wall is moved into the operating position. After a sufficient vacuum has been created, the process gas has been supplied, and microwave ignition has occurred, the plasma coating or other plasma treatment can be carried out. After a treatment has been completed, the sleeve-like chamber wall is moved again, the treated workpiece can be removed, and a new workpiece can be inserted for treatment.

Advantageous assistance from gravity is obtained by carrying out the positioning in a vertical direction.

The feeding of operating agents and the supplying of power with a simple structural design are assisted by leaving the chamber floor and the chamber lid in a static position relative to a station frame of the plasma station.

For coating hollow workpieces whose mouths are downwardly arranged, it is found to be advantageous for a cavity of the plasma station to be evaluated through the chamber floor.

A simple realization with respect to equipment is also supported by supplying process gas through the chamber floor.

Fast and uniform distribution of the process gas in the interior of the workpiece can be achieved by supplying the process gas to the interior of the workpiece through a lance.

To prevent ambient pressure from entering the evacuated plasma chamber, it is proposed that the chamber wall be sealed relative to the chamber floor.

The performance of a large number of opening and closing operations of the plasma chamber with little wear is assisted by effecting the sealing with a seal that is connected with the chamber wall. Alternatively, however, the seal can also be located in the area of the chamber floor.

To ensure adequate sealing of the plasma chamber, it is also proposed that the chamber wall be sealed relative to the chamber lid.

In the case of the upper seal of the plasma chamber, a high-quality seal and low wear can likewise be achieved by effecting the sealing with a seal located in the area of the chamber lid.

Still further improved sealing quality can be achieved by carrying out the sealing between an inner flange of the chamber wall and a flange of the chamber lid.

To help achieve controllable ignition of the plasma, it is proposed that microwaves generated by a microwave generator in the vicinity of the chamber lid be introduced into the cavity.

Adaptation of the microwave supply to actual operating conditions is facilitated if the microwave generator is connected with the interior of the cavity by a coupling duct.

A typical application consists in the treatment of a workpiece made of a thermoplastic material.

The method is intended especially for treating the interior of the workpiece.

A large area of application consists in the treatment of containers as the workpieces.

In this regard, it is intended especially that a beverage bottle be treated as the workpiece.

A high production rate with a high degree of reliability and high product quality can be achieved by transferring the plasma station from an input position to an output position by a rotating plasma wheel.

An increase in production capacity with only a slight increase in equipment expense can be achieved if one plasma station comprises several cavities.

In the case of the simultaneous coating of several workpieces, it is especially conceivable to position a chamber wall that is meant to provide at least two cavities.

A typical application is defined as the performance of a plasma coating as the plasma treatment.

It is intended especially that the plasma treatment be carried out with the use of a low-pressure plasma.

In the case of the coating of plastic workpieces, it has been found to be advantageous to carry out a plasma polymerization.

Good surface adhesion is promoted if at least some of the substances deposited by the plasma are organic substances.

Especially advantageous practical properties of workpieces to be used for packaging foods can be obtained if at least some of the substances deposited by the plasma are inorganic substances.

In the treatment of packages, it is intended especially that a substance that improves the barrier properties of the workpiece be deposited by the plasma.

To promote high practical quality, it is proposed that an adhesion promoter be additionally deposited on a surface of the workpiece to improve the adhesion of the substance.

High productivity can be promoted by simultaneously treating at least two workpieces in a common cavity.

Another area of application consists in the performance of a plasma sterilization as the plasma treatment.

The method can also be used to carry out a surface activation of the workpiece as the plasma treatment.

Specific embodiments of the invention are schematically illustrated in the drawings.

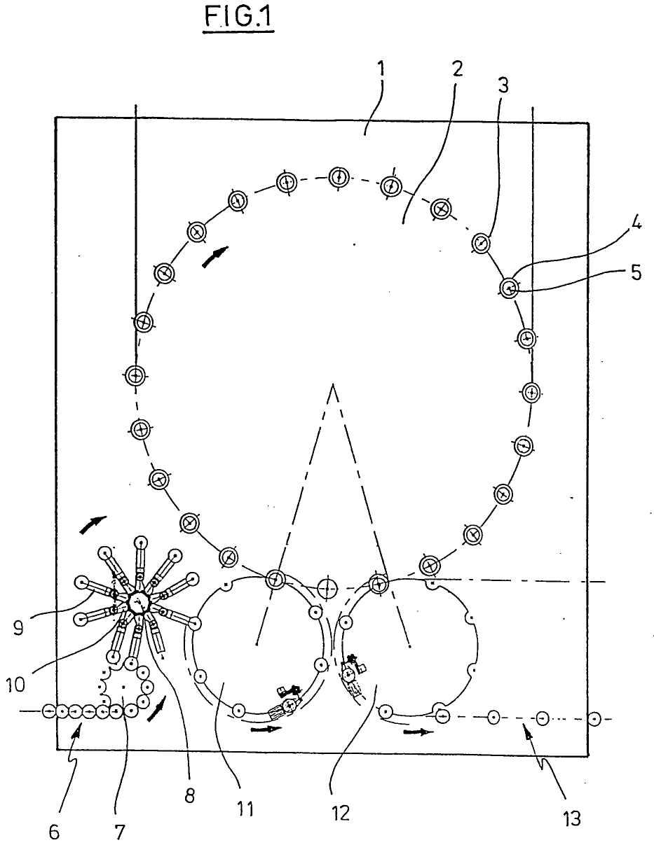

FIG. 1 shows a schematic diagram of a plurality of plasma chambers, which are arranged on a rotating plasma wheel, which is coupled with input and output wheels.

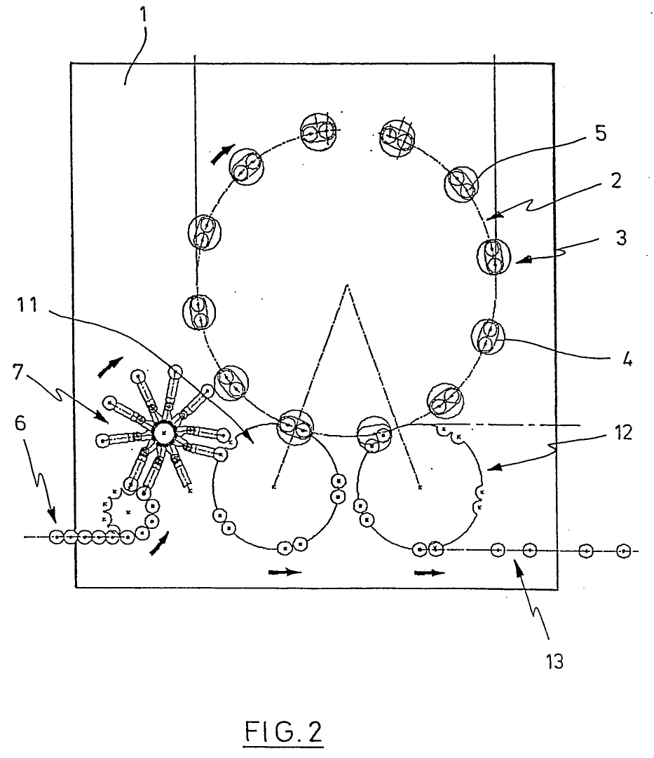

FIG. 2 shows an arrangement similar to FIG. 1, in which each plasma station is equipped with two plasma chambers.

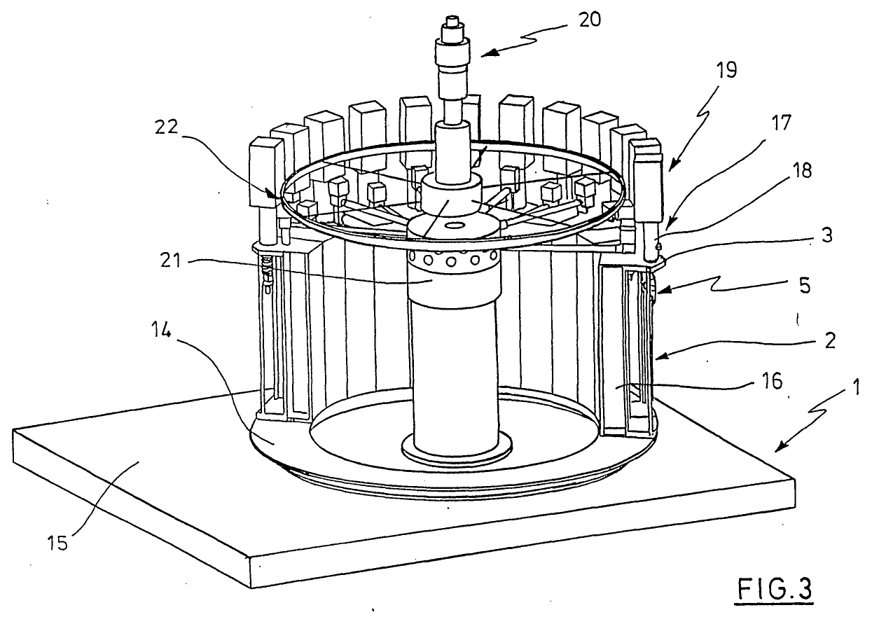

FIG. 3 shows a perspective view of a plasma wheel with a plurality of plasma chambers.

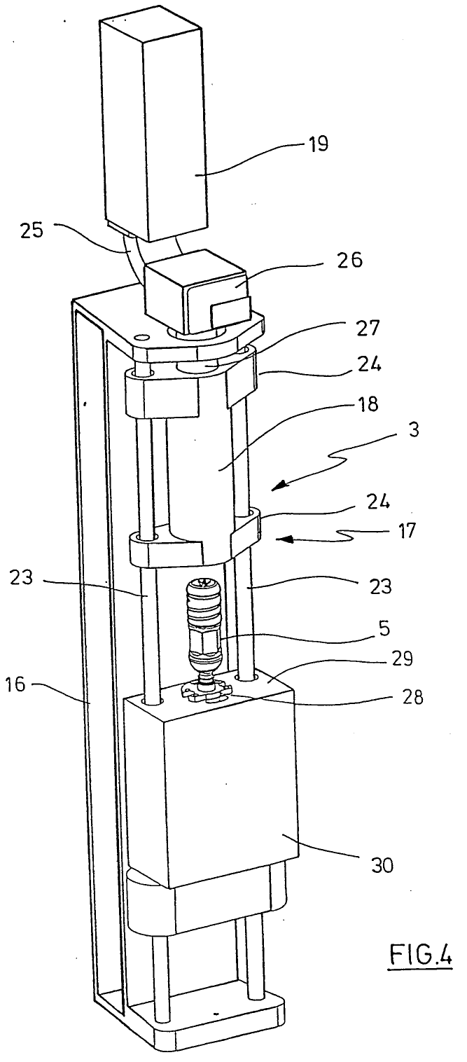

FIG. 4 shows a perspective view of a plasma station with one cavity.

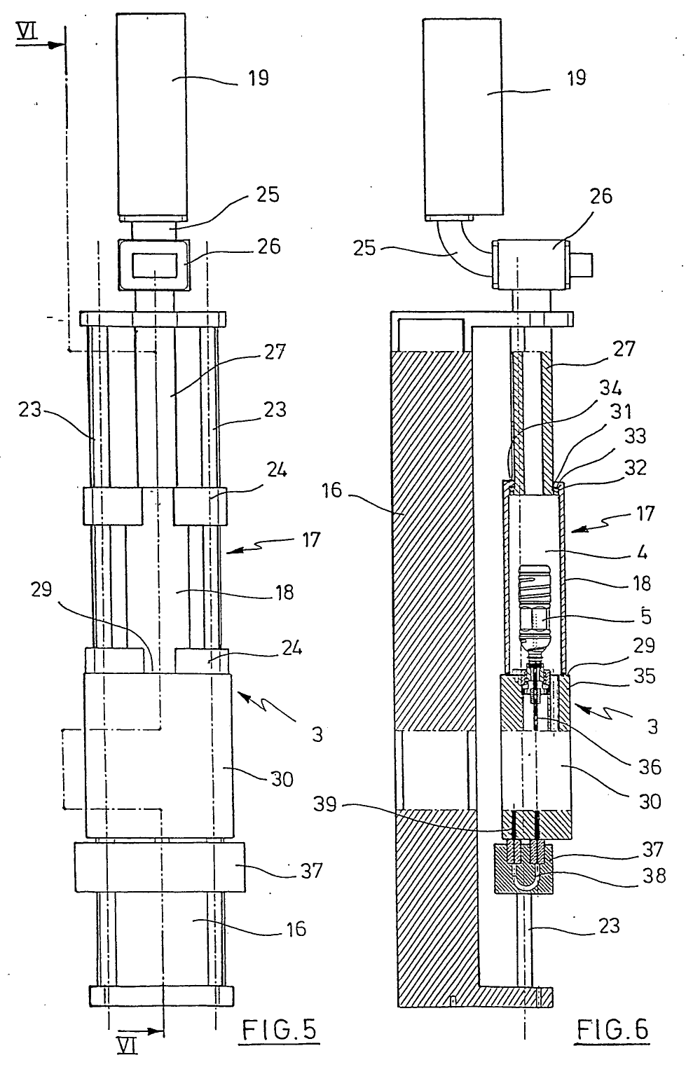

FIG. 5 shows a front elevation of the device in FIG. 4 with the plasma chamber closed.

FIG. 6 shows a cross section along cross-sectional line VI-VI in FIG. 5.

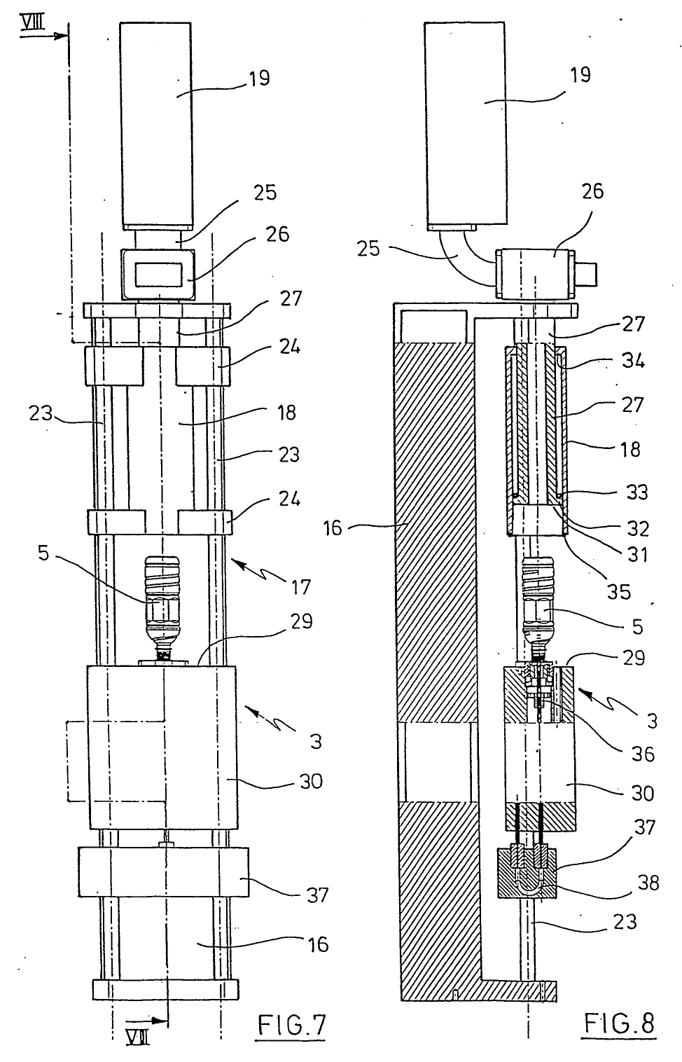

FIG. 7 shows the same view as in FIG. 5 but with the plasma chamber open.

FIG. 8 shows a vertical section along cross-sectional line VIII-VIII in FIG. 7.

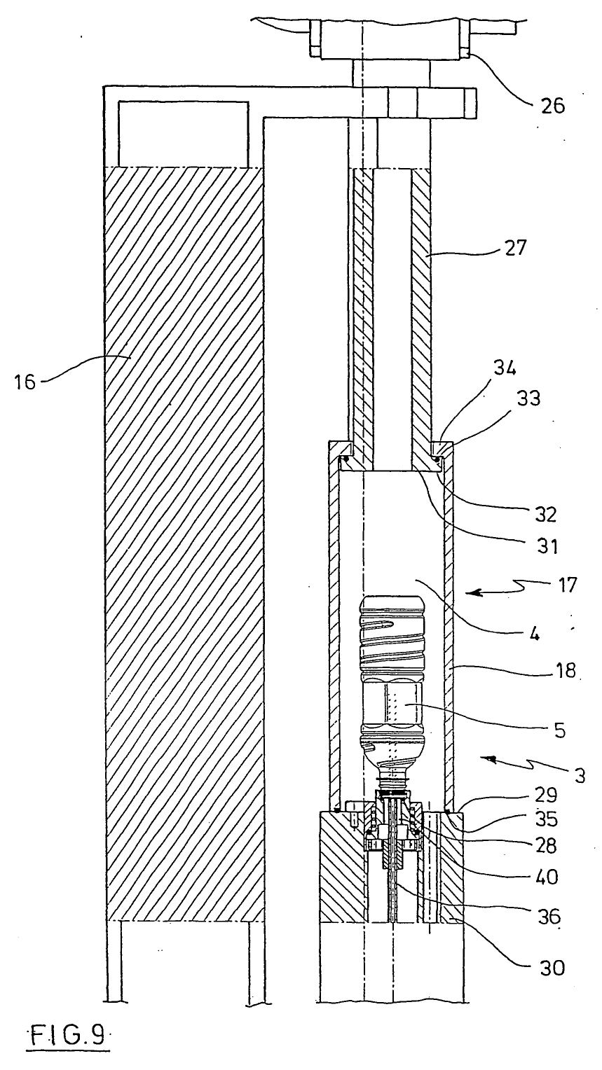

FIG. 9 shows an enlarged view of the plasma chamber with a bottle to be coated in accordance with FIG. 6.

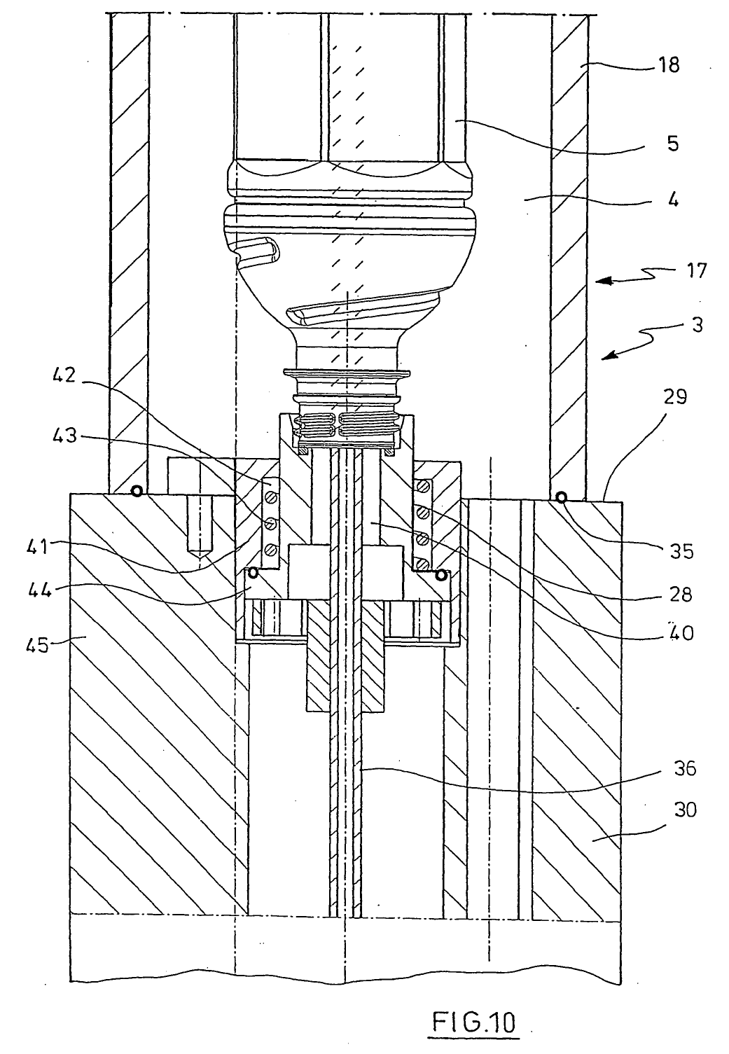

FIG. 10 shows a further enlarged view of a connecting element for mounting the workpiece in the plasma chamber.

The view in FIG. 1 shows a plasma module (1), which is provided with a rotating plasma wheel (2). A plurality of plasma stations (3) is arranged along the circumference of the plasma wheel (2). The plasma stations (3) are provided with cavities (4) and plasma chambers (17) for holding the workpieces (5) that are to be treated.

The workpieces to be treated (5) are fed to the plasma module (1) in the region of an input (6) and further conveyed by an isolating wheel (7) to a transfer wheel (8), which is equipped with positionable support arms (9). The support arms (9) are mounted in such a way that they can be swiveled relative to a base (10) of the transfer wheel (8), so that the spacing of the workpieces (5) relative to one another can be changed. In this way, the workpieces (5) are transferred from the transfer wheel (8) to an input wheel (11) with increased spacing of the workpieces (5) relative to one another compared to the isolating wheel (7). The input wheel (11) transfers the workpieces (5) to be treated to the plasma wheel (2). After the treatment has been carried but, the treated workpieces (5) are removed from the area of the plasma wheel (2) by an output wheel (12) and transferred to the area of an output line (13).

In the embodiment shown in FIG. 2, each plasma station (3) is equipped with two cavities (4) and plasma chambers (17). This makes it possible to treat two workpieces (5) at a time. In this connection, it is basically possible to design the cavities (4) completely separate, but it is also basically possible to separate only sections of a common cavity space from each other in such a way that optimum coating of all workpieces (5) is ensured. In particular, it is intended here that the cavity sections be separated from each other at least by separate microwave couplings.

FIG. 3 shows a perspective view of a plasma module (1) with a partially assembled plasma wheel (2). The plasma stations (3) are installed on a supporting ring, which is designed as part of a revolving joint and is mounted in the area of a machine base (15). Each plasma station (3) has a station frame (16), which supports plasma chambers (17). The plasma chambers (17) have cylindrical chamber walls (18) and microwave generators (19).

A rotary distributor (20), by which the plasma stations (3) are supplied with operating agents and power, is located in the center of the plasma wheel (2). Ring conduits (21) in particular can be used for distribution of the operating agents.

The workpieces (5) to be treated are shown below the cylindrical chamber walls (18). For the sake of simplicity, the lower parts of the plasma chambers (17) are not shown in the drawing.

FIG. 4 shows a perspective view of a plasma station (3). The drawing shows that the station frame (16) is provided with guide rods (23), on which a slide (24) for mounting the cylindrical chamber wall (18) is guided. FIG. 4 shows the slide (24) with the chamber wall (18) in its raised position, so that the workpiece (5) is exposed.

The microwave generator (19) is located in the upper region of the plasma station (3). The microwave generator (19) is connected by a guide (25) and an adapter (26) to a coupling duct (27), which opens into the plasma chamber (19). Basically, the microwave generator (19) can be installed directly in the vicinity of the chamber lid (31) or coupled with the chamber lid (31) at a predetermined distance from the chamber lid (31) via a spacing element and thus installed in a larger surrounding area of the chamber lid (31). The adapter (26) acts as a transition element, and the coupling duct (27) is designed as a coaxial conductor. A quartz glass window is installed in the area of the opening of the coupling duct (27) into the chamber lid (31). The guide (25) is designed as a waveguide.

The workpiece (5) is positioned by a mounting element (28), which is located in the vicinity of the chamber floor (29). The chamber floor (29) is formed as part of a chamber base (30). To facilitate adjustment, it is possible to mount the chamber base (30) in the area of the guide rods (23). An alternative is to mount the chamber base (30) directly on the station frame (16). In an arrangement of this type, it is also possible, for example, to design the guide rods (23) in two parts in the vertical direction.

FIG. 5 shows a front elevation of the plasma station (3) of FIG. 3 with the plasma chamber (17) closed. The slide (24) with the cylindrical chamber wall (18) is lowered here relative to the position in FIG. 4, so that the chamber wall (18) is moved against the chamber floor (29). In this position, the plasma coating can be carried out.

FIG. 6 shows a vertical sectional view of the arrangement in FIG. 5. It is especially apparent that the coupling duct (27) opens into a chamber lid (31), which has a laterally projecting flange (32). A seal (33), which is acted upon by an inner flange (34) of the chamber wall (18), is located in the area of the flange (32). When the chamber wall (18) is lowered, the chamber wall (18) becomes sealed relative to the chamber lid (31). Another seal (35) is located in the lower region of the chamber wall (18) to ensure sealing relative to the chamber floor (29).

In the position shown in FIG. 6, the chamber wall (18) encloses the cavity (4), so that both the interior of the cavity (4) and the interior of the workpiece (5) can be evacuated. To assist with the introduction of process gas, a hollow lance (36) is mounted in the area of the chamber base (30) and can be moved into the interior of the workpiece (5). To allow positioning of the lance (36), the lance is supported by a lance slide (37), which can be positioned along the guide rods (23). A process gas duct (38) runs inside the lance slide (37). In its raised position shown in FIG. 6, the process gas duct (38) is coupled with a gas connection (39) of the chamber base (30). This arrangement eliminates hose-like connecting elements on the lance slide (37).

FIGS. 7 and 8 show the arrangement of FIGS. 5 and 6 with the chamber wall (18) in its raised position. When the chamber wall (18) is positioned in this way, the treated workpiece (5) can be removed from the area of the plasma station (3) without any problems, and a new workpiece (5) to be treated can be inserted. Alternatively to the positioning of the chamber wall (18) that is shown in the drawing, with the plasma chamber (17) in an open state produced.by upward movement of the chamber wall (18), it is also possible to perform the opening operation by moving a structurally modified, sleeve-like chamber wall vertically downward.

In the illustrated embodiment, the coupling duct (27) has a cylindrical shape and is arranged essentially coaxially with the chamber wall (18).

FIG. 9 shows a vertical section in accordance with FIG. 6 in an enlarged partial view of the area around the chamber wall (18). Especially evident in the drawing are the overlapping of the inner flange (34) of the chamber wall (18) over the flange (32) of the chamber lid (31) and the mounting of the workpiece (5) by the mounting element (28). Furthermore, the drawing shows that the lance (36) passes through a hollow space (40) in the mounting element (28).

The further enlarged view in FIG. 10 shows the mounting of the workpiece (5) by the mounting element (28). The mounting element (28) is inserted in a guide bush (41), which is provided with a spring chamber (42). A compression spring (43) is inserted in the spring chamber (42) and secures an outer flange (44) of the mounting element (28) in place relative to the guide bush (41).

In the position shown in FIG. 10, a push disk (45) mounted on the lance is moved towards the outer flange (44) and pushes the mounting element (28) into its upper terminal position. In this position, the interior of the workpiece (5) is isolated from the interior of the cavity (4). In the lowered state of the lance (36), the compression spring (43) moves the mounting element (28) relative to the guide bush (41) in such a way that the interior of the workpiece (5) communicates with the interior of the cavity (4).

A typical treatment operation is explained below for the example of a coating operation and is carried out in such a way that the workpiece (5) is first conveyed to the plasma wheel (2) by means of the input wheel (11), and that the workpiece (5) is inserted into the plasma station (3) with the sleeve-like chamber wall (18) in its raised position. After completion of the insertion operation, the chamber wall (18) is lowered into its sealed position, and then both the cavity (4) and the interior of the workpiece (5) are evacuated, simultaneously at first.

After sufficient evacuation of the interior of the cavity (4), the lance (36) is inserted into the interior of the workpiece (5), and partitioning of the interior of the workpiece (5) from the interior of the cavity (4) is carried out by moving the mounting element (28). It is also possible to start moving the lance (36) into the workpiece (5) synchronously with the start of evacuation of the interior of the cavity. The pressure in the interior of the workpiece (5) is then further reduced. Moreover, it is also possible to carry out the positioning movement of the lance (36) at least partly at the same time as the positioning of the chamber wall (18). After a sufficiently deep negative pressure has been achieved, process gas is introduced into the interior of the workpiece (5), and the plasma is ignited by means of the microwave generator (19). In particular, it is intended that the plasma be used to deposit both an adhesion promoter on the inner surface of the workpiece (5) and the actual barrier layer consisting of silicon oxides.

After a coating operation has been completed, the lance (36) is withdrawn from the interior of the workpiece (5), and the plasma chamber (17) and the interior of the workpiece (5) are ventilated. After ambient pressure has been established inside the cavity (4), the chamber wall (18) is raised again to allow the coated workpiece (5) to be removed and a new workpiece (5) to be inserted for coating.

Alternatively to the coating of the internal surface of workpieces (5) that was explained above, it is also possible to coat the external surface or to carry out sterilization or surface activation.

The chamber wall (18), the sealing element (28), and/or the lance (36) can be positioned by means of various types of drive equipment. In principle, it is possible to use pneumatic drives and/or electric drives, especially in the form of linear drives. In particular, however, it is also possible to realize a cam mechanism to help achieve exact coordination of motion with the rotation of the plasma wheel (2). For example, the cam mechanism can be designed in such a way that control cams, along which cam followers are driven, are arranged along the circumference of the plasma wheel (2). The cam followers are coupled with the given components that are to be positioned.

1. Method for the plasma treatment of workpieces, wherein the workpiece is inserted in a chamber of a treatment station, which can be at least partially evacuated, and wherein, to assist in the handling of the workpieces, at least one part of the treatment station is moved relative to at least one other part, wherein a sleeve-like chamber wall (18) is positioned relative to a chamber floor (29) and relative to a chamber lid (31).

2. Method in accordance with claim 1, wherein the positioning is carried out in a vertical direction.

3. Method in accordance with claim 1, wherein the chamber floor (29) and the chamber lid (31) are left in a static position relative to a station frame (16) of the plasma station (3).

4. Method in accordance with claim 1, wherein a cavity (4) of the plasma station (3) is evacuated through the chamber floor (29).

5. Method in accordance with claim 1, wherein process gas is supplied through the chamber floor (29).

6. Method in accordance with claim 1, wherein the process gas is fed into the interior of the workpiece (5) through a lance (36).

7. Method in accordance with claim 1, wherein the chamber wall (18) is sealed relative to the chamber floor (29).

8. Method in accordance with claim 7, wherein the sealing is effected with a seal (35) that is connected with the chamber wall (18).

9. Method in accordance with claim 1, wherein the chamber wall (18) is sealed relative to the chamber lid (31).

10. Method in accordance with claim 9, wherein the sealing is effected with a seal (33) located in the area of the chamber lid (31).

11. Method in accordance with claim 9, wherein the sealing is carried out between an inner flange (34) of the chamber wall (18) and a flange (32) of the chamber lid (31).

12. Method in accordance with claim 1, wherein microwaves generated by a microwave generator (19) in the vicinity of the chamber lid (31) are introduced into the cavity (4).

13. Method in accordance with claim 1, wherein the microwave generator (19) is connected with the interior of the cavity (4) by a coupling duct (27).

14. Method in accordance with claim 1, wherein a workpiece (5) made of a thermoplastic material is treated.

15. Method in accordance with claim 1, wherein the interior of a workpiece (5) that is formed as a hollow body is treated.

16. Method in accordance with claim 1, wherein the workpiece (5) to be treated is a container.

17. Method in accordance with claim 1, wherein the workpiece (5) to be treated is a beverage bottle.

18. Method in accordance with claim 1, wherein the one or more plasma stations (3) are transferred from an input position to an output position by a rotating plasma wheel (2).

19. Method in accordance with claim 1, wherein several cavities (4) are supplied by one plasma station (3).

20. Method in accordance with claim 1, wherein a chamber wall (18) that is meant to provide at least two cavities (4) is positioned.

21. Method in accordance with claim 1, wherein the plasma treatment consists of a plasma coating.

22. Method in accordance with claim 1, wherein the plasma treatment is carried out with the use of a low-pressure plasma.

23. Method in accordance with claim 1, wherein a plasma polymerization is carried out.

24. Method in accordance with claim 1, wherein at least some of the substances deposited by the plasma are organic substances.

25. Method in accordance with claim 1, wherein at least some of the substances deposited by the plasma are inorganic substances.

26. Method in accordance with claim 1, wherein a substance that improves the barrier properties of the workpiece (5) is deposited by the plasma.

27. Method in accordance with claim 26, wherein an adhesion promoter is additionally deposited on a surface of the workpiece (5) to improve the adhesion of the substance.

28. Method in accordance with claim 1, wherein at least two workpieces (5) are simultaneously treated in a common cavity.

29. Method in accordance with claim 1, wherein the plasma treatment consists of plasma sterilization.

30. Method in accordance with claim 1, wherein a surface activation of the workpiece (5) is carried out as the plasma treatment.

31. Device for the plasma treatment of workpieces, which has at least one plasma chamber, which can be evacuated, for holding the workpieces, in which the plasma chamber is located in the area of a treatment station, and in which the plasma chamber is bounded by a chamber floor, a chamber lid, and a lateral chamber wall, wherein the chamber wall (18) has a sleeve-like design and is positioned both relative to the chamber floor (29) and relative to the chamber lid (31).

32. Device in accordance with claim 31, wherein the chamber wall (18) can be positioned in a vertical direction.

33. Device in accordance with claim 31, wherein the chamber floor (29) and the chamber lid (31) are arranged in a static position relative to a station frame (16) of the plasma station (3).

34. Device in accordance with claim 31, wherein at least one vacuum duct is located in the chamber floor (29) for evacuating a cavity (4) of the plasma station (3).

35. Device in accordance with claim 31, wherein at least one duct for supplying process gas is located in the chamber floor (29).

36. Device in accordance with claim 31, wherein a lance (36) can be positioned relative to the chamber floor (29) for feeding process gas into the interior of the workpiece (5).

37. Device in accordance with claim 31, wherein the chamber wall (18) is sealed relative to the chamber floor (29).

38. Device in accordance with claim 37, wherein a seal (35) is installed for sealing in the area of the chamber wall (18).

39. Device in accordance with claim 31, wherein the chamber wall (18) is sealed relative to the chamber lid (31).

40. Device in accordance with claim 39, wherein a seal (33) is installed for sealing in the area of the chamber lid (31).

41. Device in accordance with claim 39, wherein the seal (33) is located between an inner flange (34) of the chamber wall (18) and a flange (32) of the chamber lid (31).

42. Device in accordance with claim 31, wherein a microwave generator (19) is installed in the vicinity of the chamber lid (31).

43. Device in accordance with claim 31, wherein the microwave generator (19) is connected with the interior of the cavity (4) by a coupling duct (27).

44. Device in accordance with claim 31, wherein the plasma station (3) is designed for coating a workpiece (5) made of a thermoplastic material.

45. Device in accordance with claim 31, wherein the plasma station (3) is designed for coating a workpiece (5) that is formed as a container.

46. Device in accordance with claim 31, wherein the plasma station (3) is designed for coating the interior of a workpiece (5) that is formed as a hollow body.

47. Device in accordance with claim 31, wherein the plasma station (3) is designed for coating a workpiece (5) in the form of a beverage bottle.

48. Device in accordance with claim 31, wherein the one or more plasma stations (3) are supported by a rotating plasma wheel (2).

49. Device in accordance with claim 31, wherein several cavities (4) are arranged in the area of the plasma station (3).

50. Device in accordance with claim 31, wherein a chamber wall (18) meant to provide at least two cavities (4) is arranged in such a way that it can be positioned.
